(19) United States
(12) Patent Application Publication
(10) Pub. No.: US 2025/0062241 A1
(43) Pub. Date: Feb. 20, 2025

(54) SEMICONDUCTOR PACKAGE INCLUDING A PLURALITY OF SEMICONDUCTOR CHIPS

(71) Applicant: SAMSUNG ELECTRONICS CO., LTD., SUWON-SI (KR)

(72) Inventors: Kyungdon MUN, Suwon-si (KR); Jihwang KIM, Suwon-si (KR); Sangjin BAEK, Suwon-si (KR); Kuwon LEE, Suwon-si (KR)

(21) Appl. No.: 18/653,116

(22) Filed: May 2, 2024

(30) Foreign Application Priority Data
Aug. 18, 2023 (KR) 10-2023-0108265

(51) Int. Cl. H01L 23/538; H01L 23/00; H01L 23/31; H01L 23/367; H01L 23/427; H01L 25/18; H10B 80/00

(52) U.S. Cl. CPC H01L 23/5386; H01L 23/3128; H01L 23/5389; H01L 24/05; H01L 24/08; H01L 24/16; H01L 25/18; H10B 80/00; H01L 23/367; H01L 23/427; H01L 24/06; H01L 24/17; H01L 24/32; H01L 24/73; H01L 2224/05624; H01L 2224/05644; H01L 2224/05647; H01L 2224/05655; H01L 2224/06181; H01L 2224/08145; H01L 2224/08225; H01L 2224/16145; H01L 2224/16227; H01L 2224/17181; H01L 2224/32225; H01L 2224/73204; H01L 2224/73253; H01L 2924/1431; H01L 2924/1436; H01L 2924/14511

(57) ABSTRACT

A semiconductor package includes: a first substrate; a bridge chip disposed on the first substrate and having a first region and a second region; an upper semiconductor chip disposed on the first region of the bridge chip; and conductive posts disposed on the second region of the bridge chip and spaced apart from the upper semiconductor chip, wherein the upper semiconductor chip is electrically connected to the conductive posts through the bridge chip.

### CROSS-REFERENCE TO RELATED APPLICATION

This application claims priority under 35 U.S.C. § 119 to Korean Patent Application No. 10-2023-0108265, filed on Aug. 18, 2023, in the Korean Intellectual Property Office, the disclosure of which is incorporated by reference herein in its entirety.

### TECHNICAL FIELD

Embodiments of the present inventive concept relate to a semiconductor package, and more particularly, to a semiconductor package including a plurality of semiconductor chips.

### DISCUSSION OF THE RELATED ART

Generally, semiconductor packages are integrated circuit chips implemented in a form suitable for use in electronic products. Typically, in such semiconductor packages, a semiconductor chip is mounted on a printed circuit board (PCB), and the semiconductor chip is electrically connected to the PCB by using bonding wires or bumps. As the electronics industry continues to develop, various studies have been conducted to increase the reliability of semiconductor packages and achieve the high integration and miniaturization of semiconductor packages.

### SUMMARY

According to embodiments of the present inventive concept, a semiconductor package includes: a first substrate; a bridge chip disposed on the first substrate and having a first region and a second region; an upper semiconductor chip disposed on the first region of the bridge chip; and conductive posts disposed on the second region of the bridge chip and spaced apart from the upper semiconductor chip, wherein the upper semiconductor chip is electrically connected to the conductive posts through the bridge chip.

According to embodiments of the present inventive concept, a semiconductor package includes: a first substrate; a first semiconductor chip disposed on the first substrate; a bridge chip disposed on the first substrate and spaced apart from the first semiconductor chip; a second semiconductor chip disposed on a first region of the bridge chip and the first semiconductor chip, wherein the second semiconductor chip is electrically connected to the bridge chip and the first semiconductor chip; and a conductive post disposed on a second region of the bridge chip and spaced apart from the second semiconductor chip, wherein the conductive post is electrically connected to the bridge chip.

According to embodiments of the present inventive concept, a semiconductor package includes: a first redistribution substrate; solder ball terminals disposed on a lower surface of the first redistribution substrate; a first semiconductor chip mounted on the first redistribution substrate and including a through-via; a bridge chip disposed on the first redistribution substrate and spaced apart from the first semiconductor chip, wherein the bridge chip has a first region and a second region; a second semiconductor chip disposed on the first semiconductor chip and the first region of the bridge chip, wherein the second semiconductor chip is electrically connected to the first semiconductor chip and the bridge chip; conductive posts disposed on the second region of the bridge chip and spaced apart from the first semiconductor chip; interconnection structures disposed on the first redistribution substrate and spaced apart from the bridge chip, the conductive posts, and the second semiconductor chip; a first molding layer disposed on the first redistribution substrate and covering the bridge chip, the first semiconductor chip, the second semiconductor chip, sidewalls of the conductive posts, and sidewalls of the interconnection structures; a second redistribution substrate disposed on the first molding layer and electrically connected to the conductive posts and the interconnection structures; an upper package disposed on the second redistribution substrate and vertically overlapping the conductive posts; and a heat dissipation structure disposed on the second redistribution substrate, and spaced apart from the semiconductor package, wherein the heat dissipation structure vertically overlaps the second semiconductor chip, wherein the second semiconductor chip is electrically connected to the upper package through the bridge chip, the conductive posts, and the second redistribution substrate, wherein the bridge chip includes: a base substrate; a bridge insulating layer disposed on the base substrate; first connection pads disposed on an upper surface of the bridge insulating layer and electrically connected to chip pads of the second semiconductor chip; second connection pads disposed on the upper surface of the bridge insulating layer and spaced apart from the first connection pads; and connection structures disposed in the bridge insulating layer, wherein the first connection pads are respectively electrically connected to the second connection pads through the connection structures, and the conductive posts are respectively disposed on the second connection pads.

### BRIEF DESCRIPTION OF THE DRAWINGS

The above and other aspects of the present inventive concept will become more apparent by describing in detail embodiments thereof, with reference to the accompanying drawings, in which:

FIG. 1A is a plan view illustrating a semiconductor package according to embodiments of the present inventive concept;

FIG. 1B is a cross-sectional view of the semiconductor package of FIG. 1A taken along line I-II of FIG. 1A;

FIG. 1C is an enlarged view of region III of the semiconductor package of FIG. 1B;

FIG. 2A is a diagram illustrating a first semiconductor chip and a second semiconductor chip according to embodiments of the present inventive concept and is an enlarged view of region IV of FIG. 1B;

FIG. 2B is a diagram illustrating the first semiconductor chip and the second semiconductor chip according to embodiments of the present inventive concept;

FIG. 3 is a diagram illustrating an upper package according to embodiments of the present inventive concept and is an enlarged view of region V of FIG. 1B;

FIG. 4A is a diagram illustrating a semiconductor package according to embodiments of the present inventive concept;

FIG. 4B is an enlarged view of region IV of FIG. 4A;

FIG. 5 is a diagram illustrating a semiconductor package according to embodiments of the present inventive concept;

FIG. 6 is a diagram illustrating a semiconductor package according to embodiments of the present inventive concept;

FIG. 7 is a diagram illustrating a semiconductor package according to embodiments of the present inventive concept; and

FIG. 8 is a diagram illustrating a semiconductor module according to embodiments of the present inventive concept.

### DETAILED DESCRIPTION OF THE EMBODIMENTS

Like reference numerals may denote like elements throughout the specification, and thus redundant descriptions may be omitted or briefly discussed. A semiconductor package and a method of manufacturing the same, according to embodiments of the present inventive concept, will be described.

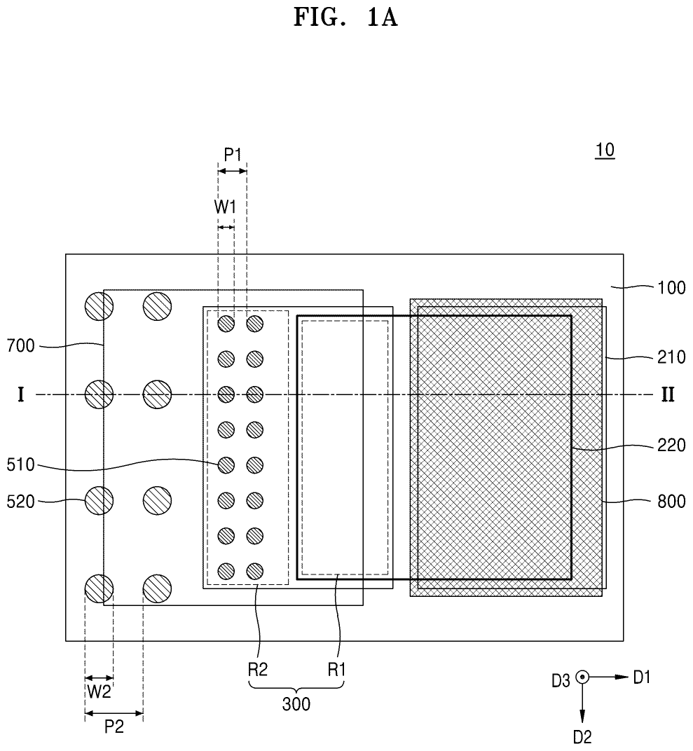

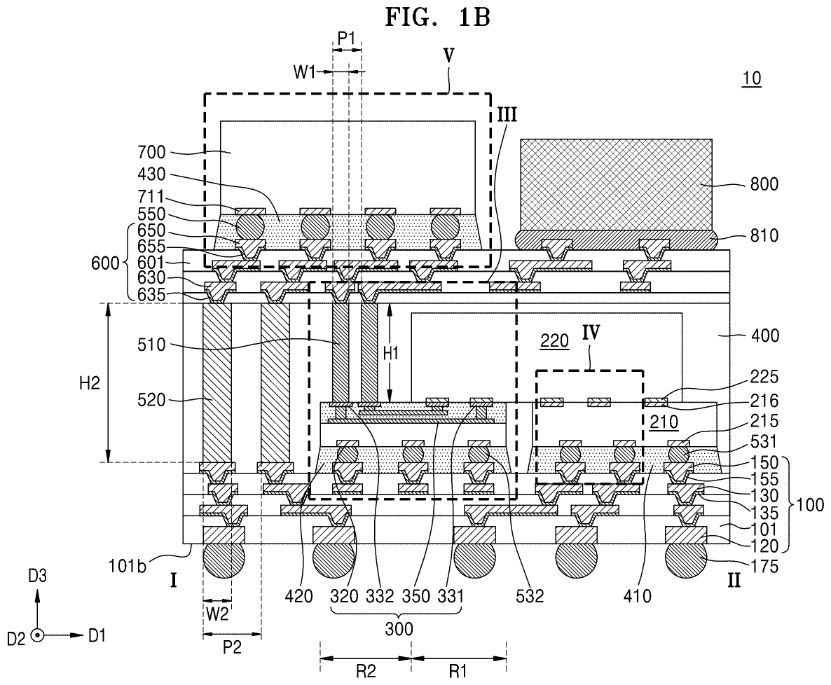

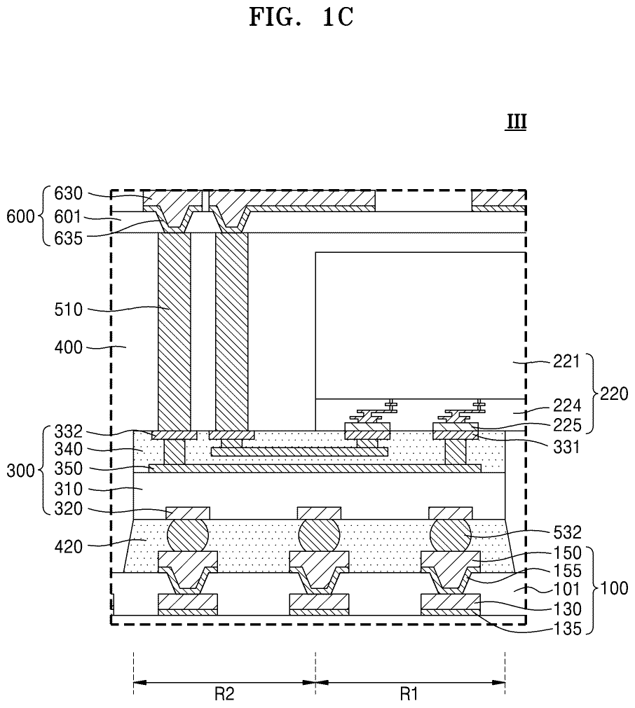

FIG. 1A is a plan view illustrating a semiconductor package 10 according to embodiments of the present invention. FIG. 1B is a cross-sectional view of the semiconductor package 10 of FIG. 1A taken along line I-II of FIG. 1A. FIG. 1C is an enlarged view of region III of the semiconductor package 10 of FIG. 1B.

Referring to FIGS. 1A and 1B, the semiconductor package 10 may include a first substrate 100, solder ball terminals 175, a first semiconductor chip 210, a second semiconductor chip 220, a bridge chip 300, conductive posts 510, interconnection structures 520, a first molding layer 400, a second substrate 600, an upper package 700, and a heat dissipation structure 800.

As an example, the first substrate 100 may be a redistribution substrate. As another example, the first substrate 100 may include a printed circuit board (PCB), such as a multi-layer board (MLB) and/or a high-density interconnection (HDI) board. For convenience, FIGS. 1B, IC, 2A, 2B, 4A, 4B, 5, 6, 7, and 8 illustrate a case where the first substrate 100 is a redistribution substrate, but the present inventive concept is not limited thereto. The type of the first substrate 100 and the components of the first substrate 100 may be variously modified.

When the first substrate 100 is a redistribution substrate, the first substrate 100 may include a first insulating pattern 101, under-bump patterns 120, first redistribution patterns 130, first seed patterns 135, first seed pads 155, and first redistribution pads 150. The expression “being electrically connected to the first substrate 100” may mean “being electrically connected to one of the first redistribution patterns 130.” An electrical connection between two components may include a direct connection and an indirect connection through other components. A first direction D1 may be parallel to a bottom surface 101b of a lowermost first insulating pattern 101 among first insulating patterns 101. A second direction D2 may be parallel to the bottom surface 101b of the lowermost first insulating pattern 101 and substantially perpendicular to the first direction D1. A third direction D3 may be substantially perpendicular to the first direction D1 and the second direction D2. The first insulating pattern 101, the under-bump patterns 120, the first redistribution patterns 130, the first seed patterns 135, the first seed pads 155, and the first redistribution pads 150 are described below in detail.

The solder ball terminals 175 may be disposed on the lower surface of the first substrate 100. For example, the solder ball terminals 175 may be respectively disposed on the lower surfaces of the under-bump patterns 120 and electrically connected to the under-bump patterns 120. The solder ball terminals 175 may be respectively electrically connected to the first redistribution patterns 130 through the under-bump patterns 120. The solder ball terminals 175 may be laterally spaced apart from each other and electrically separated from each other. For example, the solder ball terminals 175 may be horizontally spaced apart from one another. The term “horizontal” may mean “parallel to the bottom surface 101b of the first substrate 100.” The solder ball terminals 175 may each include a solder material. The solder material may include, for example, tin, bismuth, lead, silver, or any alloy thereof. The solder ball terminals 175 may include a signal solder ball, a ground solder ball, and a power solder ball.

The first semiconductor chip 210 may be mounted on the upper surface of the first substrate 100. The first semiconductor chip 210 may be a lower semiconductor chip. The first semiconductor chip 210 may be, for example, a logic chip or a buffer chip. For example, the first semiconductor chip 210 may be a chiplet.

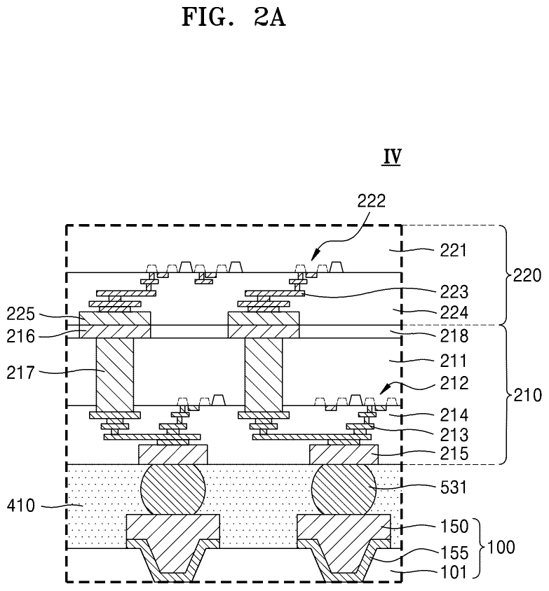

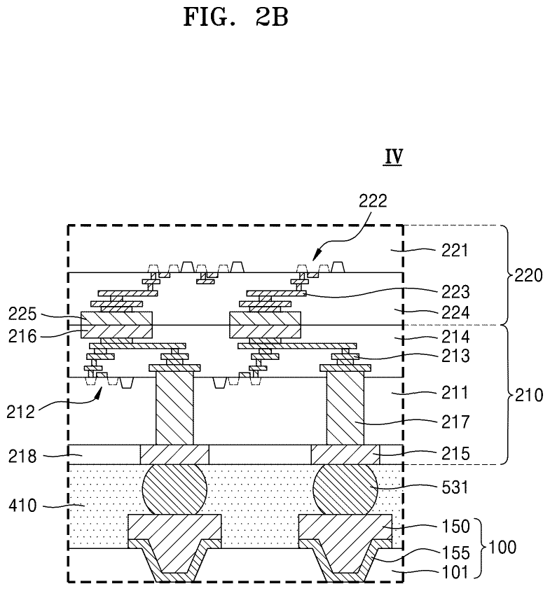

The first semiconductor chip 210 may include lower pads 215 and upper pads 216. The lower pads 215 and the upper pads 216 may be respectively provided on the lower surface and the upper surface of the first semiconductor chip 210. The lower pads 215 or the upper pads 216 may be electrically connected to first integrated circuits (see 212 of FIGS. 2A and 2B) of the first semiconductor chip 210. The lower pads 215 may be chip pads and/or the upper pads 216 may be chip pads. The expression “the component is electrically connected to the semiconductor chip” may mean that the component is electrically connected to the integrated circuits of the semiconductor chip through the chip pads of the semiconductor chip. For example, the lower pads 215 and the upper pads 216 may each include metal, such as copper, aluminum, nickel, and/or gold (Au).

The bridge chip 300 may be disposed on the upper surface of the first substrate 100 and may be laterally spaced apart from the first semiconductor chip 210. The bridge chip 300 may have a first region R1 and a second region R2 in a plan view. The first region R1 of the bridge chip 300 may be disposed between the second region R2 and the first semiconductor chip 210.

As illustrated in FIG. 1C, the bridge chip 300 may include a base substrate 310, a bridge insulating layer 340, a connection structure 350, a first connection pad 331, and a second connection pad 332. The base substrate 310 may be, for example, a semiconductor substrate such as a silicon substrate. As another example, the base substrate 310 may include an organic substrate. The organic substrate may include an insulating polymer. The bridge insulating layer 340 may be disposed on the upper surface of the base substrate 310. The bridge insulating layer 340 may be a single layer or multiple layers. For example, the bridge insulating layer 340 may include a silicon-based insulating material or an organic insulating material. The silicon-based insulating material may include, for example, silicon oxide, silicon nitride, silicon oxynitride, silicon carbide oxide, and/or any combination thereof. The organic insulating material may include an insulating polymer.

The first connection pad 331 and the second connection pad 332 may be disposed on or in the bridge insulating layer 340. The upper surface of the first connection pad 331 and the upper surface of the second connection pad 332 might not be covered by the bridge insulating layer 340. The first connection pad 331 and the second connection pad 332 may be laterally spaced apart from each other. For example, the first connection pad 331 may be disposed on the first region R1 of the bridge chip 300, and the second connection pad 332 may be disposed on the second region R2 of the bridge chip 300. For example, the first connection pad 331 and the second connection pad 332 may each include metal, such as copper, aluminum, and/or tungsten.

The connection structure 350 may be disposed in the bridge insulating layer 340 and connected to the first connection pad 331 and the second connection pad 332. Accordingly, the first connection pad 331 may be electrically connected to the second connection pad 332 through the connection structure 350. The expression “being electrically connecting to the bridge chip 300” may mean “being electrically connected to at least one of the first connection pad 331, the second connection pad 332, and/or the connection structure 350.”

The bridge chip 300 may include a plurality of first connection pads 331, a plurality of second connection pads 332, and a plurality of connection structures 350. The first connection pads 331 are spaced apart from each other and electrically separated from each other. The second connection pads 332 are spaced apart from each other and electrically separated from each other. The first connection pads 331 may be respectively electrically connected to the second connection pads 332 through the connection structures 350. The connection structures 350 may be insulated from each other. The connection structures 350 may each include conductive vias and conductive wirings. In the present specification, the conductive vias may be for vertical connection, and the conductive wirings may be for horizontal connection. The term “vertical” may mean “parallel to the third direction D3.” The connection structures 350 may each include metal, such as copper, titanium, and/or tungsten.

The bridge chip 300 might not include integrated circuits, but the present inventive concept is not limited thereto. As an example, the bridge chip 300 may further include passive elements, such as capacitors, resistors, and/or inductors.

The second semiconductor chip 220 may be disposed on the first semiconductor chip 210 and the bridge chip 300, as illustrated in FIG. 1B. The second semiconductor chip 220 may be an upper semiconductor chip. The second semiconductor chip 220 may be disposed on a portion of the first semiconductor chip 210 and spaced apart from another portion of the first semiconductor chip 210 in a plan view. A first portion of the first semiconductor chip 210 may be disposed between the bridge chip 300 and a second portion of the first semiconductor chip 210 in a plan view. The central axis of the second semiconductor chip 220 may be shifted from the central axis of the first semiconductor chip 210 in a direction opposite to the first direction D1. The second semiconductor chip 220 may be electrically connected to the first semiconductor chip 210. For example, the second semiconductor chip 220 may include second chip pads 225 disposed on the lower surface of the second semiconductor chip 220. Some of the second chip pads 225 of the second semiconductor chip 220 may be respectively electrically connected to the upper pads 216 of the first semiconductor chip 210. For example, the second semiconductor chip 220 may be directly bonded to the first semiconductor chip 210. The direct bonding between the first semiconductor chip 210 and the second semiconductor chip 220 is described below with reference to FIGS. 2A and 2B.

The second semiconductor chip 220 may be a logic chip. For example, the second semiconductor chip 220 may be a logic chip that performs a function that is different from a function of the first semiconductor chip 210. The second semiconductor chip 220 may include a second semiconductor die 221, a second insulating layer 224, and second chip pads 225, as illustrated in FIG. 1C. The second semiconductor die 221 may include a semiconductor material and may have a crystalline structure. The semiconductor material may include, for example, silicon, germanium, or silicon-germanium. The second insulating layer 224 may be disposed on the lower surface of the second semiconductor die 221. The second insulating layer 224 may include a silicon-based insulating material or an organic material. The second chip pads 225 may be disposed on the lower surface of the second semiconductor chip 220. For example, the second insulating layer 224 may cover the sidewalls of the second chip pads 225, but might not cover the lower surfaces of the second chip pads 225. The thickness of the second semiconductor chip 220 may be greater than the thickness of the first semiconductor chip 210. The thickness of the second semiconductor chip 220 may be equal to the gap between the upper surface and the lower surface of the second semiconductor chip 220.

For example, the second semiconductor chip 220 may be a chiplet. The chiplet may include at least one of intellectual property (IP) block units formed by dividing a logic semiconductor chip by function. The logic semiconductor chip may constitute a single processor and operate as a single processor. In addition, each of a plurality of chiplets does not operate as an independent processor, but the chiplets may be connected to each other and operate as at least one processor. In other words, the processor may include chiplets connected to each other.

When the second semiconductor chip 220 is a chiplet, second integrated circuits (see 222 of FIGS. 2A and 2B) of the second semiconductor chip 220 may form at least one IP block unit. When the first semiconductor chip 210 is a chiplet, first integrated circuits (see 212 of FIGS. 2A and 2B) of the first semiconductor chip 210 may form at least one IP block unit. The IP block unit of the second semiconductor chip 220 may have a function and a design that are different from a function and a design of the IP block unit of the first semiconductor chip 210. When the first semiconductor chip 210 and the second semiconductor chip 220 are each a chiplet, the first semiconductor chip 210 and the second semiconductor chip 220 may constitute a single processor and operate as a single processor. The processor may function as, for example, an application specific integrated circuit (ASIC) or an application processor (AP). As another example, the processor may function as a central processing unit (CPU) or a graphics processing unit (GPU).

As another example, each of the first semiconductor chip 210 and the second semiconductor chip 220 might not be a chiplet. In this case, the first semiconductor chip 210 and the second semiconductor chip 220 may operate independently of each other.

The second semiconductor chip 220 may be disposed on the upper surface of the bridge chip 300 in the first region R1 and spaced apart from the upper surface of the bridge chip 300 in the second region R2 in a plan view. Other portions of the second chip pads 225 of the second semiconductor chip 220 may vertically overlap the first connection pads 331 and may be electrically connected to the first connection pads 331. The other portions of the second chip pads 225 may be electrically connected to the second connection pads 332 through the first connection pads 331 and the connection structures 350. Accordingly, the second semiconductor chip 220 may be electrically connected to the bridge chip 300.

According to embodiments of the present inventive concept, the upper surface of the bridge chip 300 may be provided at the same or similar level as the upper surface of the first semiconductor chip 210. A level of a certain component may refer to a vertical level. For example, the vertical gap between the upper surface of the bridge chip 300 and the upper surface of the first substrate 100 may be about 95% to about 105% of the vertical gap between the upper surface of the first semiconductor chip 210 and the upper surface of the first substrate 100. Accordingly, the second semiconductor chip 220 may be electrically connected to the first semiconductor chip 210 and the bridge chip 300 and may be disposed on the first semiconductor chip 210 and the bridge chip 300.

The second semiconductor chip 220 may be bonded to the bridge chip 300. For example, the second semiconductor chip 220 may be directly bonded to the bridge chip 300. The direct bonding between two chips may include hybrid bonding. The direct bonding between two chips may include direct bonding between conductive components of the two chips that face each other and direct bonding between insulating components of the two chips that face each other. The direct bonding between the insulating components may include forming a chemical bond between the insulating components. For example, the second chip pads 225 may be directly bonded to the first connection pads 331. During the direct bonding process, metal atoms in the second chip pads 225 may diffuse into the first connection pads 331, and metal atoms in the first connection pads 331 may diffuse into the second chip pads 225. The interface between the second chip pads 225 and the first connection pads 331 might not be distinguished, but the present inventive concept is not limited thereto.

As illustrated in FIG. 1C, the second insulating layer 224 may be bonded to the bridge insulating layer 340. For example, the second insulating layer 224 may be directly bonded to the bridge insulating layer 340. For example, the second insulating layer 224 may be in direct contact with the bridge insulating layer 340, and a chemical bond such as a covalent bond may be formed between the second insulating layer 224 and the bridge insulating layer 340. For example, the second insulating layer 224 may be connected to the bridge insulating layer 340 without an interface. Accordingly, the interface between the second insulating layer 224 and the bridge insulating layer 340 might not be distinguished. In FIGS. 1B and 1C, the interface between the second insulating layer 224 and the bridge insulating layer 340 may be a virtual interface, but the present inventive concept is not limited thereto.

The conductive posts 510 may be disposed on the upper surface of the second region R2 of the bridge chip 300. The conductive posts 510 may be laterally spaced apart from the second semiconductor chip 220. The conductive posts 510 may be laterally spaced apart from each other and electrically separated from each other. The conductive posts 510 may be disposed on the second connection pads 332 and electrically connected to the second connection pads 332. Accordingly, the second semiconductor chip 220 may be electrically connected to the conductive posts 510 through the bridge chip 300. The conductive posts 510 may transmit an electrical signal from the second semiconductor chip 220.

As illustrated in FIG. 1B, each of the conductive posts 510 may have a first height H1. The first height H1 may be about 250 μm to about 350 μm. Each of the conductive posts 510 may have a first width W1. The first width W1 may be about 80 μm to about 120 μm. The conductive posts 510 may have a first pitch P1. The first pitch P1 may be about 100 μm to about 200 μm. Because the first width W1 is about 80 μm or more and the first pitch P1 is about 100 μm or more, the conductive posts 510 may have structural stability. Because the first width W1 is about 120 μm or less and the first pitch P1 is about 200 μm or less, a large number of conductive posts 510 may be disposed on the second region R2 of the bridge chip 300.

The interconnection structures 520 may be disposed on the upper surface of the first substrate 100. The interconnection structures 520 may be laterally spaced apart from the bridge chip 300, the conductive posts 510, the first semiconductor chip 210, and the second semiconductor chip 220. The bridge chip 300 may be disposed between the interconnection structures 520 and the first semiconductor chip 210 in a plan view. The interconnection structures 520 may each have a cylindrical shape; however, the present inventive concept is not limited thereto. The interconnection structures 520 may be respectively disposed on the corresponding first redistribution pads 150 and electrically connected to the first redistribution pads 150. The interconnection structures 520 may function as an electrical path between the first substrate 100 and the second substrate 600. The upper surfaces of the interconnection structures 520 may be disposed at substantially the same level as the upper surfaces of the conductive posts 510. The interconnection structures 520 may have a second height H2. The second height H2 may be greater than the first height H1. For example, the second height H2 may be about 300 μm to about 400 μm. The interconnection structures 520 may have a second width W2. The second width W2 may be greater than the first width W1. The interconnection structures 520 may have a second pitch P2. The second pitch P2 may be greater than the first pitch P1. The interconnection structures 520 may include, for example, metal such as copper or tungsten.

The first molding layer 400 may be disposed on the upper surface of the first substrate 100 and may cover the bridge chip 300, the first semiconductor chip 210, and the second semiconductor chip 220. The first molding layer 400 may cover the sidewalls of the interconnection structures 520 and the sidewalls of the conductive posts 510. The first molding layer 400 might not extend to the upper surfaces of the interconnection structures 520 and the upper surfaces of the conductive posts 510. The upper surface of the first molding layer 400 may be substantially coplanar with the upper surfaces of the interconnection structures 520 and the upper surfaces of the conductive posts 510. The first molding layer 400 may include an insulating polymer such as an epoxy-based molding compound (EMC).

The second substrate 600 may be disposed on the second semiconductor chip 220, the first molding layer 400, the interconnection structures 520, and the conductive posts 510. The second substrate 600 may be electrically connected to the conductive posts 510 and the interconnection structures 520. As an example, the second substrate 600 may be a redistribution substrate. As another example, the second substrate 600 may include a printed circuit board (PCB), such as an MLB and/or an HDI board. For convenience, FIGS. 1B, IC, 4A, 4B, 5, 6, 7, and 8 illustrate a case where the second substrate 600 is a redistribution substrate, but the present inventive concept is not limited thereto. The type of the second substrate 600 and the components of the second substrate 600 may be variously modified.

As an example, when the second substrate 600 is a redistribution substrate, the second substrate 600 may include a second insulating pattern 601, second redistribution patterns 630, second seed patterns 635, second seed pads 655, and second redistribution pads 650. The second insulating pattern 601, the second redistribution patterns 630, the second seed patterns 635, the second seed pads 655, and the second redistribution pads 650 are described below in detail.

The upper package 700 may be disposed on the second substrate 600 and electrically connected to the second substrate 600. The upper package 700 may be a memory package. The upper package 700 may overlap at least a portion of the second semiconductor chip 220 in a plan view. The upper package 700 may be electrically connected to the conductive posts 510 through the second substrate 600. Accordingly, the second semiconductor chip 220 may be electrically connected to the upper package 700 through the bridge chip 300, the conductive posts 510, and the second substrate 600. The bridge chip 300 and the conductive posts 510 may function as an electrical signal path between the second semiconductor chip 220 and the upper package 700. The electrical signal may include, for example, a data signal or a processing signal. The electrical signal transmission between the second semiconductor chip 220 and the upper package 700 might not pass through the first substrate 100. Because the bridge chip 300 and the conductive posts 510 are provided, the length of the electrical signal path between the second semiconductor chip 220 and the upper package 700 may be reduced. Accordingly, the transmission rate of the electrical signal between the upper package 700 and the conductive posts 510 may increase. The upper package 700 may overlap the conductive posts 510 in a plan view. Accordingly, the length of the electrical signal path between the upper package 700 and the conductive posts 510 may be further reduced.

The first width W1 and the first pitch P1 of each of the conductive posts 510 may be relatively small. Because the first width W1 is about 120 μm or less and the first pitch P1 is about 200 μm or less, the conductive posts 510 may be suitable for signal transmission between highly integrated input/output (I/O) terminals. According to embodiments of the present inventive concept, the second semiconductor chip 220 and the upper package 700 may be highly integrated, and the second semiconductor chip 220 and the upper package 700 may transmit and receive electrical signals therebetween through the conductive posts 510 at high speed. The performance of the semiconductor package 10 may be increased.

According to embodiments of the present inventive concept, the upper package 700 may overlap the conductive posts 510, the bridge chip 300, and the second semiconductor chip 220 in a plan view, and the second semiconductor chip 220 may overlap the first semiconductor chip 210 in a plan view. Accordingly, the planar area of the semiconductor package 10 may be reduced and the semiconductor package 10 may be miniaturized.

The upper package 700 may overlap about 20% to about 40% of the planar area of the second semiconductor chip 220 in a plan view. Because the upper package 700 overlaps more than about 20% of the planar area of the second semiconductor chip 220 in a plan view, the planar area of the semiconductor package 10 may be reduced. Because the upper package 700 overlaps less than about 40% of the planar area of the second semiconductor chip 220, the number of conductive posts 510 may be sufficient for signal transmission between the upper package 700 and the second semiconductor chip 220. The upper package 700 may be further miniaturized and may have increased performance.

The upper package 700 may be electrically connected to the interconnection structures 520 through the second substrate 600. When the interconnection structures 520 are used as a signal transmission path between the second semiconductor chip 220 and the upper package 700, the length of the signal path between the second semiconductor chip 220 and the upper package 700 may increase. According to embodiments of the present inventive concept, the interconnection structures 520 may function as a voltage supply path. For example, the upper package 700 may receive a voltage through the interconnection structures 520. The voltage may be a power supply voltage or a ground voltage. According to embodiments of the present inventive concept, because the interconnection structures 520 have a relatively large second pitch P2 and a relatively large second width W2, a voltage may be stably supplied to the upper package 700.

As an example, at least one of the interconnection structures 520 may be used as a signal transmission path between the upper package 700 and the corresponding solder ball terminal 175. In this case, the upper package 700 may transmit and receive signals to and from an external device through the at least one interconnection structure 520 and the corresponding solder ball terminal 175.

The upper package 700 may overlap at least one of the interconnection structures 520 in a plan view. In this case, the planar area of the semiconductor package 10 may be further reduced and the semiconductor package 10 may be further miniaturized.

The heat dissipation structure 800 may be disposed on the second substrate 600 and laterally spaced apart from the upper package 700. For example, the heat dissipation structure 800 may be adjacent to the upper package 700. The heat dissipation structure 800 may overlap the second semiconductor chip 220 and the first semiconductor chip 210 in a plan view. When the semiconductor package 10 operates, heat generated in the first semiconductor chip 210 and the second semiconductor chip 220 may be transferred to the heat dissipation structure 800 through the second substrate 600. The heat dissipation structure 800 may have relatively high thermal conductivity. Accordingly, heat may be quickly dissipated to the outside through the heat dissipation structure 800. The semiconductor package 10 may exhibit increased thermal and operational characteristics.

The heat dissipation structure 800 may include, for example, a heat slug or a heat sink. The heat dissipation structure 800 may include metal (e.g., copper and/or aluminum, etc.) or a carbon-containing material (e.g., graphene, graphite, and/or carbon nanotubes, etc.). As an example, a single metal layer or a plurality of stacked metal layers may be used as the heat dissipation structure 800.

The heat dissipation structure 800 may vertically overlap the second redistribution patterns 630 and the second redistribution pads 650. The second redistribution patterns 630 and the second redistribution pads 650 may have relatively high thermal conductivity. For example, the thermal conductivity of the second redistribution patterns 630 and the thermal conductivity the second redistribution pads 650 may be greater than the thermal conductivity of the second insulating pattern 601. Accordingly, heat generated in the first semiconductor chip 210 and the second semiconductor chip 220 may be effectively transferred to the heat dissipation structure 800 through the second redistribution patterns 630 and the second redistribution pads 650.

The semiconductor package 10 may further include a thermal interface material (TIM) layer 810. The TIM layer 810 may be disposed between the second substrate 600 and the heat dissipation structure 800. The TIM layer 810 may include, for example, a polymer and thermally conductive particles. The thermally conductive particles may be dispersed within the polymer. The thermally conductive particles may include metal. The TIM layer 810 may have a thermal conductivity greater than a thermal conductivity of air. Because the TIM layer 810 is provided, heat generated in the first semiconductor chip 210 and the second semiconductor chip 220 may be more effectively transferred to the heat dissipation structure 800 through the TIM layer 810.

According to embodiments of the present inventive concept, because the thickness of the first semiconductor chip 210 is less than the thickness of the second semiconductor chip 220, heat generated in the first semiconductor chip 210 may be more quickly transferred to the heat dissipation structure 800 through the second semiconductor chip 220.

Hereinafter, the first substrate according to an embodiment of the present inventive concept is described in more detail.

When the first substrate 100 is a redistribution substrate, the first substrate 100 may include a first insulating pattern 101, under-bump patterns 120, first redistribution patterns 130, first seed patterns 135, first seed pads 155, and first redistribution pads 150. The first insulating pattern 101 may include an organic material such as a photo-imageable dielectric (PID) material. The PID material may be a polymer. The PID material may include, for example, at least one of photosensitive polyimide, polybenzoxazole, phenol-based polymer, and benzocyclobutene-based polymer. A plurality of first insulating patterns 101 may be provided. The number of stacked first insulating patterns 101 may be variously changed. As an example, the first insulating patterns 101 may include the same material as one another. The interface between the first insulating patterns 101 adjacent to each other might not be distinguished.

The under-bump patterns 120 may be disposed in the lowermost first insulating pattern 101. The bottom surfaces of the under-bump patterns 120 might not be covered by the lowermost first insulating pattern 101. The under-bump patterns 120 may function as pads of the solder ball terminals 175. The under-bump patterns 120 may be laterally spaced apart from each other and electrically insulated from each other. The under-bump patterns 120 may include a metal material such as copper.

The first redistribution patterns 130 may be disposed on the under-bump patterns 120 and electrically connected to the under-bump patterns 120. The first redistribution patterns 130 may include metal such as copper.

The first redistribution patterns 130 may each include a first via portion and a first wiring portion. The first via portion may be disposed in the corresponding first insulating pattern 101. The first wiring portion may be disposed on the first via portion and connected to the first via portion without an interface. The width of the first wiring portion may be greater than the width of the first via portion. The first wiring portion may extend to the upper surface of the corresponding first insulating pattern 101.

The first redistribution patterns 130 may include stacked first lower redistribution patterns and first upper redistribution patterns. The first lower redistribution pattern may be disposed on the corresponding under-bump pattern 120. The first upper redistribution pattern may be disposed on the first lower redistribution pattern and electrically connected to the first lower redistribution pattern.

The first seed patterns 135 may be respectively disposed on the lower surfaces of the first redistribution patterns 130. For example, the first seed patterns 135 may respectively cover the lower surfaces and sidewalls of the first via portions of the first redistribution patterns 130 and the lower surfaces of the first wiring portions of the first redistribution patterns 130. The first seed patterns 135 may include a material that is different from each of a material of the under-bump patterns 120 and a material of the first redistribution patterns 130. For example, the first seed patterns 135 may include a conductive seed material. The conductive seed material may include, for example, copper, titanium, and/or any alloy thereof. The first seed patterns 135 may function as barrier layers that prevent diffusion of materials included in the first redistribution patterns 130.

The first redistribution pads 150 may be disposed in the uppermost first insulating pattern 101 and extend to the upper surface of the uppermost first insulating pattern 101. The lower portion of each of the first redistribution pads 150 may be disposed in the uppermost first insulating pattern 101. The upper portion of each of the first redistribution pads 150 may be disposed on the upper surface of the uppermost first insulating pattern 101. The upper portion of each of the first redistribution pads 150 may have a width greater than a width of the lower portion of each of the first redistribution pads 150 and may be connected to the lower portion of each of the first redistribution pads 150. The first redistribution pads 150 may be laterally spaced apart from each other. The first redistribution pads 150 may be disposed on the first redistribution patterns 130 and electrically connected to the first redistribution patterns 130. At least one of the first redistribution pads 150 may be electrically connected to the corresponding under-bump pattern 120 through the first upper redistribution pattern and the first lower redistribution pattern. Because the first redistribution patterns 130 are provided, one of the first redistribution pads 150 might not be vertically aligned with the under-bump pattern 120 that is electrically connected thereto. Accordingly, the arrangement of the first redistribution pads 150 may be designed more freely. The number of first redistribution patterns 130 that are stacked between the under-bump patterns 120 and the first redistribution pads 150 is not limited to that illustrated and may be variously changed.

The first seed pads 155 may be respectively disposed on the lower surfaces of the first redistribution pads 150. The first seed pads 155 may be disposed between the first upper redistribution patterns of the first redistribution patterns 130 and the first redistribution pads 150 and may extend between the uppermost first insulating pattern 101 and the first redistribution pads 150. The first seed pads 155 may include a material that is different from a material of the first redistribution pads 150. The first seed pads 155 may include, for example, a conductive seed material.

The semiconductor package 10 may further include first lower bumps 531. The first lower bumps 531 may be disposed between the first substrate 100 and the first semiconductor chip 210. For example, the first lower bumps 531 may be respectively disposed between the first redistribution pads 150 and the lower pads 215 and electrically connected to the first redistribution pads 150 and the lower pads 215. Accordingly, the first semiconductor chip 210 may be electrically connected to the first substrate 100 through the first lower bumps 531. The first semiconductor chip 210 may be electrically connected to the solder ball terminals 175 through the first substrate 100. The first lower bumps 531 may include solder balls. The solder balls may include a solder material. The first lower bumps 531 may further include pillar patterns. The pillar patterns may include a metal that is different than the solder material. The pillar patterns may include, for example, copper.

The semiconductor package 10 may further include a first underfill layer 410. The first underfill layer 410 may be disposed in a first gap region between the first substrate 100 and the first semiconductor chip 210 and may cover the sidewalls of the first lower bumps 531. The first underfill layer 410 may include an insulating polymer such as epoxy polymer. The first underfill layer 410 may include an insulating polymer that is different from an insulating polymer of the first molding layer 400. As an example, the first underfill layer 410 may be omitted and the first molding layer 400 may extend to the first gap region.

The bridge chip 300 may further include metal pads 320, as illustrated in FIG. 1C. The metal pads 320 may be disposed on the lower surface of the bridge chip 300. For example, the metal pads 320 may be spaced apart from the connection structures 350 and electrically insulated from the connection structures 350. The metal pads 320 may function as dummy pads.

The semiconductor package 10 may further include second lower bumps 532. The second lower bumps 532 may be disposed between the first substrate 100 and the bridge chip 300. For example, the second lower bumps 532 may be respectively disposed between the first redistribution pads 150 and the metal pads 320 and electrically connected to the first redistribution pads 150 and the metal pads 320. The second lower bumps 532 may be spaced apart from the connection structures 350 and might not be electrically connected to the connection structures 350. The second lower bumps 532 may be dummy bumps. For example, the second lower bumps 532 may support the bridge chip 300, but might not be electrically connected to the bridge chip 300. The second lower bumps 532 may include solder balls. The second lower bumps 532 may further include pillar patterns. The pillar patterns may include a metal that is different than the solder material.

The semiconductor package 10 may further include a second underfill layer 420. The second underfill layer 420 may be disposed in a second gap region between the first substrate 100 and the bridge chip 300 and may cover the sidewalls of the second lower bumps 532. The second underfill layer 420 may include an insulating polymer such as epoxy polymer. The second underfill layer 420 may include an insulating polymer that is different from an insulating polymer of the first molding layer 400. As an example, the second underfill layer 420 may be omitted and the first molding layer 400 may extend to the second gap region.

Hereinafter, the configurations of the second substrate 600 according to an embodiment of the present invention are described in detail.

The second substrate 600 may include a plurality of second insulating patterns 601. The second insulating patterns 601 may be stacked on the first molding layer 400. The second insulating patterns 601 may include a PID material. As an example, the second insulating patterns 601 may include the same material as each other. The interface between the second insulating patterns 601 that are adjacent to each other might not be distinguished. The number of second insulating patterns 601 may be variously changed.

The second redistribution patterns 630 may be disposed in and on the second insulating patterns 601. The second redistribution patterns 630 may each include a second via portion and a second wiring portion. The second via portion may be disposed in the corresponding second insulating pattern 601. The second wiring portion may be disposed on the second via portion and connected to the second via portion without an interface. The width of the second wiring portion of each of the second redistribution patterns 630 may be greater than the width of the second via portion. The second wiring portion of each of the second redistribution patterns 630 may extend to the upper surface of the corresponding second insulating pattern 601. The second redistribution patterns 630 may each include metal such as copper.

The second redistribution patterns 630 may include stacked second lower redistribution patterns and second upper redistribution patterns. The second lower redistribution pattern may be disposed on the corresponding conductive post 510 or the corresponding interconnection structure 520 and electrically connected to the conductive post 510 or the interconnection structure 520. The second upper redistribution pattern may be disposed on the second lower redistribution pattern and electrically connected to the second lower redistribution pattern.

The second seed patterns 635 may be respectively disposed on the lower surfaces of the second redistribution patterns 630. For example, the second seed patterns 635 may be respectively disposed on the lower surfaces and sidewalls of the second via portions of the corresponding second redistribution patterns 630 and may extend to the lower surfaces of the second wiring portions. The second seed patterns 635 may each include a material that is different from each of materials of the conductive posts 510, the interconnection structures 520, and the second redistribution patterns 630. For example, the second seed patterns 635 may each include a conductive seed material. The second seed patterns 635 may function as barrier layers that prevent diffusion of materials included in the second redistribution patterns 630.

The second redistribution pads 650 may be respectively disposed on the corresponding second redistribution patterns 630 and electrically connected to the corresponding second redistribution patterns 630. For example, the second redistribution pads 650 may be respectively disposed on the second upper redistribution patterns. The second redistribution pads 650 may be laterally spaced apart from each other. The lower portions of the second redistribution pads 650 may be disposed in the uppermost second insulating pattern 601. The upper portions of the second redistribution pads 650 may extend to the upper surface of the uppermost second insulating pattern 601. The second redistribution pads 650 may each include metal such as copper.

The second redistribution pads 650 may be respectively electrically connected to the conductive posts 510 or the interconnection structures 520 through the second redistribution patterns 630 and the second seed pattern 635. Because the second redistribution patterns 630 are provided, at least one second redistribution pad 650 might not be vertically aligned with the conductive post 510 or the interconnection structure 520 that is electrically connected thereto. Accordingly, the arrangement of the second redistribution pads 650 may be designed more freely. The number of second redistribution patterns 630 stacked between the conductive posts 510 and the second redistribution pads 650 is not limited to that illustrated and may be variously changed. For example, one second redistribution pattern 630 or three or more second redistribution patterns 630 may be disposed between the conductive posts 510 and the second redistribution pads 650.

The second seed pads 655 may be disposed between the uppermost second redistribution patterns 630 and the second redistribution pads 650. The second seed pads 655 may each include a conductive seed material.

The semiconductor package 10 may further include upper bumps 550. The upper bumps 550 may be disposed between the second substrate 600 and the upper package 700. The upper package 700 may include lower conductive pads 711. The upper bumps 550 may be respectively disposed between the corresponding second redistribution pads 650 and the corresponding lower conductive pads 711 and electrically connected to the second redistribution pads 650 and the lower conductive pads 711. Accordingly, the upper package 700 may be electrically connected to the second substrate 600 through the upper bumps 550. The upper bumps 550 may include solder balls. The upper bumps 550 may further include pillar patterns.

The semiconductor package 10 may further include a third underfill layer 430. The third underfill layer 430 may be disposed in a third gap region between the second substrate 600 and the upper package 700 and may cover the sidewalls of the upper bumps 550. The third underfill layer 430 may include an insulating polymer such as epoxy polymer. As another example, the third underfill layer 430 may be omitted.

FIG. 2A is a diagram illustrating the first semiconductor chip 210 and the second semiconductor chip 220 according to embodiments of the present inventive concept and is an enlarged view of region IV of FIG. 1B. Hereinafter, the same description as provided above is omitted.

Referring to FIGS. 1B and 2A, the first semiconductor chip 210 may include a first semiconductor die 211, first integrated circuits 212, a first wiring layer, lower pads 215, through-vias 217, a rear insulating layer 218, and upper pads 216. The first semiconductor die 211 may include a semiconductor material and may have a crystalline structure. The lower surface of the first semiconductor die 211 may face the first substrate 100. The lower surface of the first semiconductor die 211 may be a front surface, and the upper surface of the first semiconductor die 211 may be a rear surface. The first integrated circuits 212 may include logic circuits and may be disposed on the lower surface of the first semiconductor die 211.

The first wiring layer may be disposed on the lower surface of the first semiconductor die 211. The first wiring layer may include a front-end-of-line (FEOL) layer and a back-end-of-line (BEOL) layer. The first wiring layer may include a first insulating layer 214 and first conductive wirings 213. The first insulating layer 214 may be disposed on the lower surface of the first semiconductor die 211 and may cover the first integrated circuits 212. The first insulating layer 214 may be a single layer or multiple layers. The first conductive wirings 213 may be disposed in the first insulating layer 214 and connected to the first integrated circuits 212. The lower pads 215 may be disposed on the lower surface of the first semiconductor chip 210. For example, the lower pads 215 may be exposed by the lower surface of the first semiconductor chip 210. The lower surface of the first semiconductor chip 210 may include the lower surface of the first insulating layer 214. The first insulating layer 214 may cover the sidewalls of the lower pads 215 but might not cover the lower surfaces of the lower pads 215. The lower pads 215 may be electrically connected to the first integrated circuits 212 through the first conductive wirings 213.

The through-vias 217 may pass through the first semiconductor die 211. The through-vias 217 may further pass through at least a portion of the first insulating layer 214. The through-vias 217 may be electrically connected to the lower pads 215 through the first conductive wirings 213. The through-vias 217 may each include metal such as copper and/or tungsten.

The upper pads 216 may be disposed on the upper surfaces of the through-vias 217 and electrically connected to the through-vias 217. Unlike that illustrated in FIG. 2A, a via redistribution pattern may be further provided between the upper pads 216 and the through-vias 217, and the upper pads 216 may be electrically connected to the through-vias 217 through the via redistribution pattern. The rear insulating layer 218 may be disposed on the upper surface of the first semiconductor die 211 and may cover the sidewalls of the upper pads 216. The rear insulating layer 218 might not cover the upper surfaces of the upper pads 216. The rear insulating layer 218 may include, for example, a silicon-based insulating material or an organic material.

The second semiconductor chip 220 may include a second semiconductor die 221, second integrated circuits 222, a second wiring layer, and second chip pads 225. The lower surface of the second semiconductor die 221 may be a front surface. The second integrated circuits 222 may include logic circuits and may be disposed on the lower surface of the second semiconductor die 221.

The second wiring layer may be disposed on the lower surface of the second semiconductor die 221. The second wiring layer may include an FEOL layer and a BEOL layer. The second wiring layer may include a second insulating layer 224 and second conductive wirings 223. The second insulating layer 224 may be disposed on the lower surface of the second semiconductor die 221 and may cover the second integrated circuits 222. The second insulating layer 224 may be a single or multiple layers. The second conductive wirings 223 may be disposed in the second insulating layer 224 and connected to the second integrated circuits 222. The second chip pads 225 may be disposed on the lower surface of the second semiconductor chip 220. The lower surface of the second semiconductor chip 220 may include the lower surface of the second insulating layer 224. The second chip pads 225 may be electrically connected to the second integrated circuits 222 through the second conductive wirings 223. The second chip pads 225 may each include metal such as aluminum.

The second semiconductor chip 220 may be bonded to the first semiconductor chip 210. For example, the second semiconductor chip 220 may be directly bonded to the first semiconductor chip 210. For example, the second chip pads 225 may be directly bonded to the upper pads 216. During the direct bonding process, metal atoms in the second chip pads 225 may diffuse into the upper pads 216 and metal atoms in the upper pads 216 may diffuse into the second chip pads 225. Accordingly, the interface between the second chip pads 225 and the upper pads 216 might not be distinguished, but the present inventive concept is not limited thereto.

The second insulating layer 224 may be bonded to the rear insulating layer 218. For example, the second insulating layer 224 may be directly bonded to the rear insulating layer 218. For example, the second insulating layer 224 may be in direct contact with the rear insulating layer 218, and a chemical bond such as a covalent bond may be formed between the second insulating layer 224 and the rear insulating layer 218. The second insulating layer 224 may be fixed to the rear insulating layer 218 by the chemical bond. The second insulating layer 224 may be connected to the rear insulating layer 218 without an interface. Accordingly, the interface between the second insulating layer 224 and the rear insulating layer 218 might not be distinguished. In FIG. 2A, the interface between the second insulating layer 224 and the rear insulating layer 218 may be a virtual interface, but the present inventive concept is not limited thereto.

The length of electrical signal transmission between the first semiconductor chip 210 and the second semiconductor chip 220 may be reduced by the bonding between the first semiconductor chip 210 and the second semiconductor chip 220. Accordingly, the first semiconductor chip 210 and the second semiconductor chip 220 may transmit and receive electrical signals to and from each other at high speed. Because no other components are provided between the first semiconductor chip 210 and the second semiconductor chip 220, the height of the semiconductor package 10 may be reduced.

FIG. 2B is a diagram illustrating the first semiconductor chip 210 and the second semiconductor chip 220 according to embodiments of the present inventive concept and is an enlarged view of region IV of FIG. 1B. Hereinafter, the same description as provided above is omitted.

Referring to FIGS. 1B and 2B, the first semiconductor chip 210 may include a first semiconductor die 211, first integrated circuits 212, a first wiring layer, lower pads 215, through-vias 217, and upper pads 216. The first semiconductor die 211, the lower pads 215, the through-vias 217, and the upper pads 216 may be substantially the same as those described in the examples of FIG. 2A.

However, the upper surface of the first semiconductor die 211 may be a front surface, and the lower surface of the first semiconductor die 211 may be a rear surface. The first integrated circuits 212, the first insulating layer 214, and the first conductive wirings 213 may be disposed on the upper surface of the first semiconductor die 211. The upper pads 216 may be disposed on the first insulating layer 214 and may be electrically connected to at least one of the first integrated circuits 212 and the through-vias 217 through the first conductive wirings 213. The upper surfaces of the upper pads 216 might not be covered by the first insulating layer 214. The rear insulating layer 218 may be disposed on the lower surface of the first semiconductor die 211 and may cover the sidewalls of the lower pads 215.

The second semiconductor chip 220 may be bonded to the first semiconductor chip 210. For example, the second chip pads 225 may be directly bonded to the upper pads 216. For example, the second insulating layer 224 may be directly bonded to the first insulating layer 214. For example, the second insulating layer 224 may be in direct contact with the first insulating layer 214, and a chemical bond such as a covalent bond may be formed between the second insulating layer 224 and the first insulating layer 214. The second insulating layer 224 may be connected to the first insulating layer 214 without an interface. Accordingly, the interface between the second insulating layer 224 and the first insulating layer 214 might not be distinguished. In FIG. 2B, the interface between the second insulating layer 224 and the first insulating layer 214 may be a virtual interface, but the present inventive concept is not limited thereto.

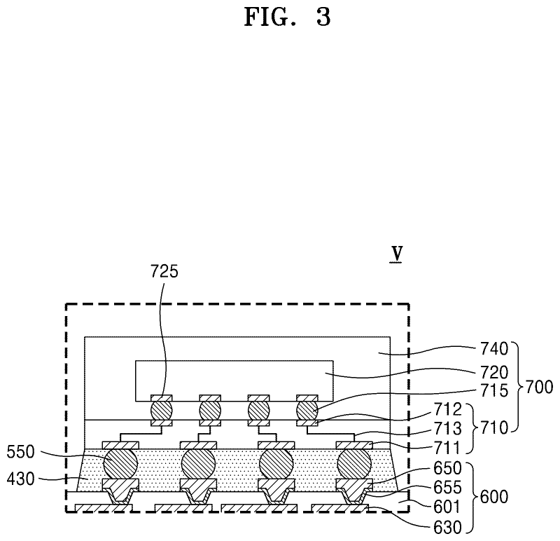

FIG. 3 is a diagram for describing the upper package 700 according to embodiments of the present inventive concept and is an enlarged view of region V of FIG. 1B.

Referring to FIGS. 1B and 3, the upper package 700 may include a package substrate 710 and a third semiconductor chip 720. The package substrate 710 may be a redistribution substrate or a PCB. The package substrate 710 may include lower conductive pads 711, conductive patterns 713, and upper conductive pads 712. The lower conductive pads 711 and the upper conductive pads 712 may be respectively disposed on the upper surface and the lower surface of the package substrate 710. The conductive patterns 713 may be disposed in the package substrate 710. The upper conductive pads 712 may be electrically connected to the lower conductive pads 711 through the conductive patterns 713. The lower conductive pads 711, the conductive patterns 713, and the upper conductive pads 712 may each include a metal material, such as copper, aluminum, and/or tungsten.

The third semiconductor chip 720 may be mounted on the package substrate 710. The type of the third semiconductor chip 720 may be different from each of the type of the first semiconductor chip 210 and the type of the second semiconductor chip 220. The third semiconductor chip 720 may include, for example, a memory chip such as dynamic random access memory (DRAM) or NAND flash memory.

For example, the third semiconductor chip 720 may be mounted by flip-chip bonding. For example, conductive bumps 715 may be disposed between the package substrate 710 and the third semiconductor chip 720 and electrically connected to the upper conductive pads 712 and the third chip pads 725 of the third semiconductor chip 720. Accordingly, the third semiconductor chip 720 may be electrically connected to the package substrate 710 through the conductive bumps 715. The conductive bumps 715 may include solder balls and/or pillar patterns.

As an example, the upper package 700 may include a plurality of third semiconductor chips 720. As an example, the conductive bumps 715 may be omitted and the third semiconductor chip 720 may be electrically connected to the package substrate 710 through bonding wires.

The upper package 700 may further include a second molding layer 740. The second molding layer 740 is disposed on the upper surface of the package substrate 710 and may cover the third semiconductor chip 720. The second molding layer 740 may include an epoxy-based molding compound.

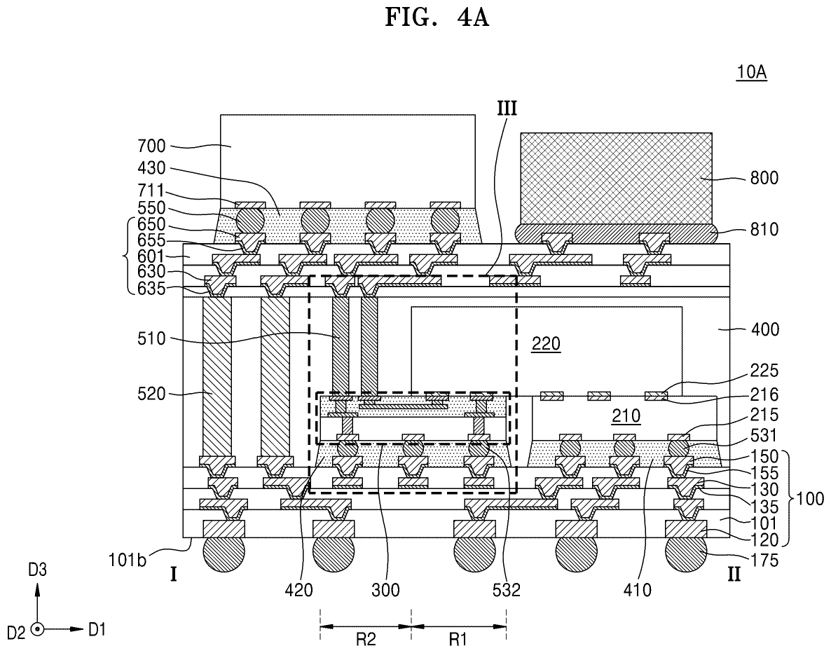

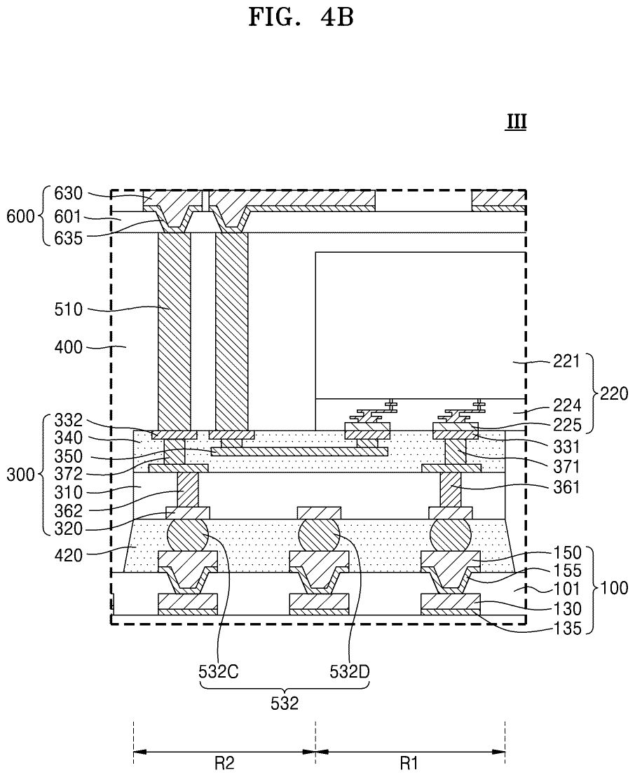

FIG. 4A is a diagram illustrating a semiconductor package 10A according to embodiments of the present inventive concept and corresponds to a cross-section taken along line I-II of FIG. 1A. FIG. 4B is an enlarged view of region IV of FIG. 4A.

Referring to FIGS. 4A and 4B, the semiconductor package 10A may include a first substrate 100, solder ball terminals 175, a first semiconductor chip 210, a second semiconductor chip 220, a bridge chip 300, conductive posts 510, interconnection structures 520, a first molding layer 400, a second substrate 600, an upper package 700, and a heat dissipation structure 800.

As illustrated in FIG. 4B, the bridge chip 300 may include a base substrate 310, a bridge insulating layer 340, connection structures 350, first connection pad 331, a second connection pad 332, and metal pads 320, and may further include a first metal pattern 371, a second metal pattern 372, a first conductive via 361, and a second conductive via 362.

The first conductive via 361 and the second conductive via 362 may be disposed in the base substrate 310 and may pass through the base substrate 310. The first conductive via 361 may be disposed on a first region R1 of the bridge chip 300, and the second conductive via 362 may be disposed on a second region R2 of the bridge chip 300. The first and second conductive vias 361 and 362 may be disposed on the metal pads 320 and electrically connected to the metal pads 320. The first conductive via 361 and the second conductive via 362 may be insulated from the connection structures 350. The first and second conductive vias 361 and 362 may each include a metal material, such as copper, titanium, tungsten, and/or any alloy thereof.

The first metal pattern 371 and the second metal pattern 372 may be disposed in the bridge insulating layer 340. The first metal pattern 371 and the second metal pattern 372 may be spaced apart from the connection structures 350 and electrically separated from the connection structures 350. The first metal pattern 371 may be disposed on the first region R1 of the bridge chip 300 and electrically connected to the first conductive via 361 and the corresponding first connection pad 331. Accordingly, the second semiconductor chip 220 may be electrically connected to the first substrate 100 through the first metal pattern 371 and the first conductive via 361.

The second metal pattern 372 may be disposed on the second region R2 of the bridge chip 300 and electrically connected to the second conductive via 362 and the corresponding second connection pad 332. Accordingly, one of the conductive posts 510 may be electrically connected to the first substrate 100 through the second metal pattern 372 and the second conductive via 362. The upper package 700 may be electrically connected to the corresponding solder ball terminal 175 through the second substrate 600, the one of the conductive posts 510, the bridge chip 300, and the first substrate 100. Accordingly, the upper package 700 may be electrically connected to an external device without passing through the second semiconductor chip 220 and the first semiconductor chip 210.

As described above, the upper package 700 may be electrically connected to the second semiconductor chip 220 through another one of the conductive posts 510 and the connection structures 350.

The first and second metal patterns 371 and 372 may each include a metal via and a metal wiring. The metal via may pass through at least a portion of the bridge insulating layer 340. The metal wiring may be electrically connected to a metal via and may have a major axis that extends horizontally. The first and second metal patterns 371 and 372 may each include, for example, copper, titanium, tungsten, and/or any alloy thereof.

Unlike those illustrated in FIGS. 4A and 4B, the first metal pattern 371 and the first conductive via 361 may be omitted. As an example, the second metal pattern 372 and the second conductive via 362 may be omitted.

According to embodiments of the present inventive concept, the second lower bumps 532 may include a connection bump 532C and a dummy bump 532D. The connection bump 532C may be disposed on the lower surface of the first conductive via 361 or the second conductive via 362 and electrically connected to the first conductive via 361 or the second conductive via 362. The dummy bump 532D may be electrically insulated from the first conductive via 361, the second conductive via 362, and the connection structures 350. The dummy bump 532D may be spaced apart from the connection bump 532C and insulated from the connection bump 532C. The dummy bump 532D might not have a signal transmission or voltage supply function. The dummy bump 532D and the connection bump 532C may support the bridge chip 300.

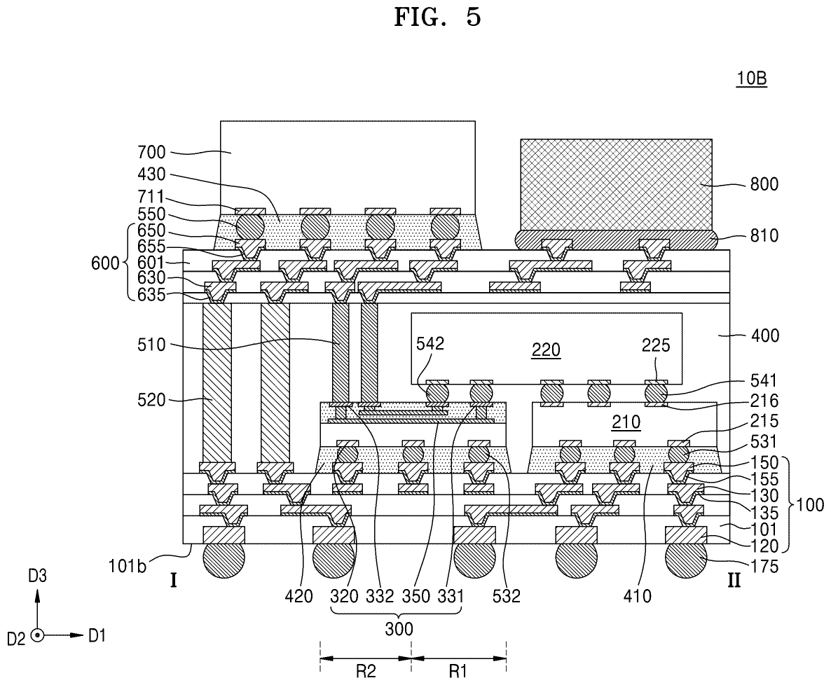

FIG. 5 is a diagram illustrating a semiconductor package 10B according to embodiments of the present inventive concept and corresponds to a cross-section taken along line I-II of FIG. 1A.

Referring to FIG. 5, the semiconductor package 10B may include a first substrate 100, solder ball terminals 175, a first semiconductor chip 210, a second semiconductor chip 220, a bridge chip 300, conductive posts 510, interconnection structures 520, a first molding layer 400, a second substrate 600, an upper package 700, and a heat dissipation structure 800, and may further include first upper bumps 541 and second upper bumps 542. The first and second upper bumps 541 and 542 may include solder balls. The first and second upper bumps 541 and 542 may further include pillar patterns.

The first upper bumps 541 may be disposed between the first semiconductor chip 210 and the second semiconductor chip 220 and electrically connected to the upper pads 216 and some second chip pads 225. Accordingly, the second semiconductor chip 220 may be electrically connected to the first semiconductor chip 210 through the first upper bumps 541.

The second upper bumps 542 may be disposed between the bridge chip 300 and the second semiconductor chip 220 and electrically connected to the first connection pads 331 and other second chip pads 225. Accordingly, the second semiconductor chip 220 may be electrically connected to the bridge chip 300 through the first upper bumps 541.

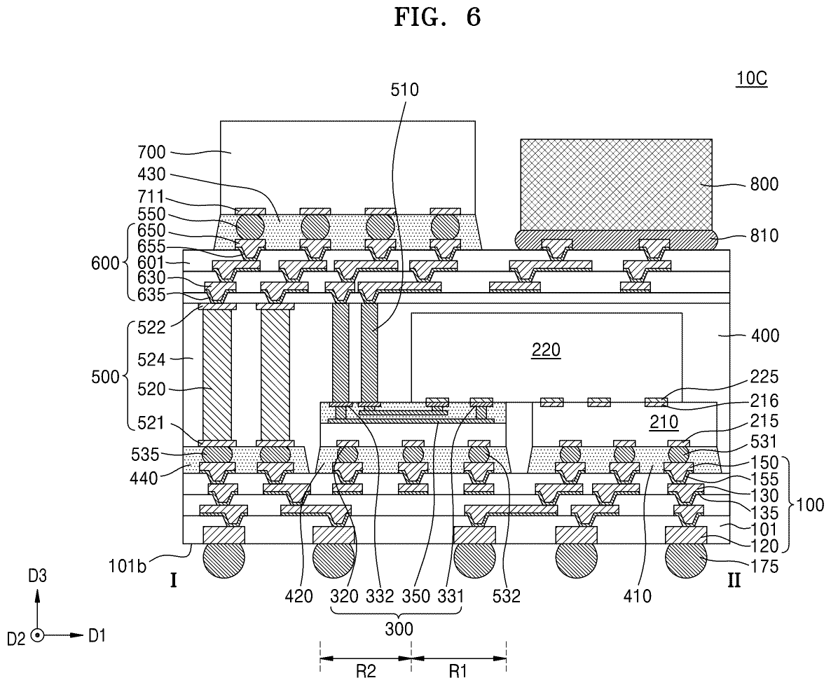

FIG. 6 is a diagram illustrating a semiconductor package 10C according to embodiments of the present inventive concept and corresponds to a cross-section taken along line I-II of FIG. 1A.

Referring to FIG. 6, the semiconductor package 10C may include a first substrate 100, solder ball terminals 175, a first semiconductor chip 210, a second semiconductor chip 220, a bridge chip 300, conductive posts 510, a first molding layer 400, a second substrate 600, an upper package 700, and a heat dissipation structure 800, and may further include a connection substrate 500 and third lower bumps 535.

The connection substrate 500 may be disposed on the upper surface of the first substrate 100 and laterally spaced apart from the bridge chip 300 and the first semiconductor chip 210. The connection substrate 500 may be a PCB. The connection substrate 500 may include a base layer 524 and interconnection structures 520. The base layer 524 may include an insulating material. The base layer 524 may include, for example, a carbon-based material, ceramic, or polymer. The interconnection structures 520 may be disposed in the base layer 524. The connection substrate 500 may further include first pads 521 and second pads 522. The first pads 521 may be disposed on the lower surfaces of the interconnection structures 520 and electrically connected to the interconnection structures 520. The second pads 522 may be disposed on the upper surfaces of the interconnection structures 520 and electrically connected to the interconnection structures 520. The second pads 522 may be electrically connected to the first pad 521 through interconnection structures 520. The second pads 522 may be exposed on the upper surface of the base layer 524. The interconnection structures 520, the first pads 521, and the second pads 522 may each include a conductive material such as metal.

The third lower bumps 535 may be disposed between the first substrate 100 and the connection substrate 500. The third lower bumps 535 may be disposed between the first pads 521 and the corresponding first redistribution pads 150 and electrically connected to the first pads 521 and the corresponding first redistribution pads 150. The interconnection structures 520 may be electrically connected to the first substrate 100 through third lower bumps 535. The third lower bumps 535 may each include at least one of a solder ball pattern and a pillar pattern.

The semiconductor package 10C may further include a fourth underfill layer 440. The fourth underfill layer 440 may be disposed in a fourth gap region between the first substrate 100 and the connection substrate 500 and may seal and cover the third lower bumps 535. For example, the fourth underfill layer 440 may include an insulating polymer. As an example, the fourth underfill layer 440 may be omitted and the first molding layer 400 may extend to the fourth gap region.

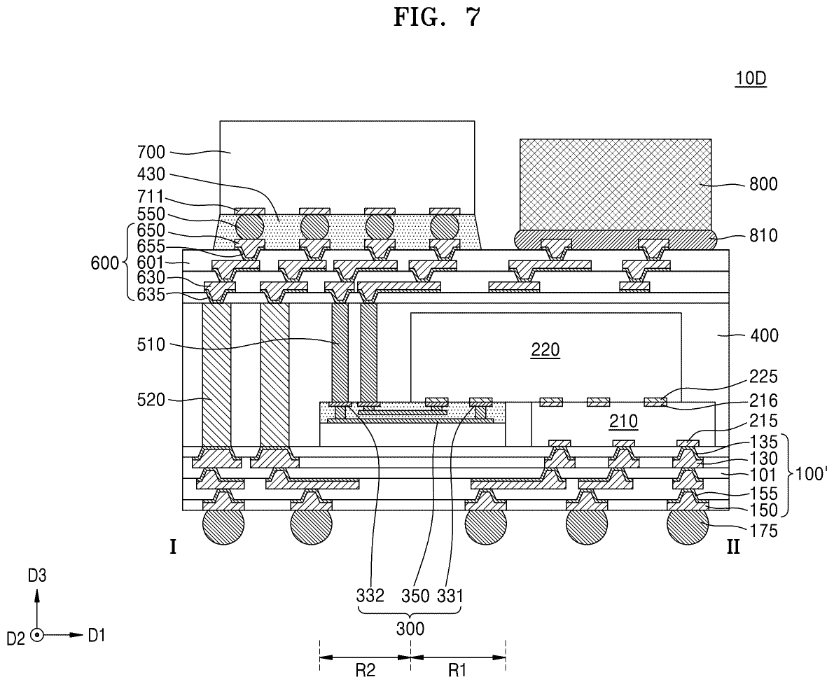

FIG. 7 is a diagram illustrating a semiconductor package 10D according to embodiments of the present inventive concept and corresponds to a cross-section taken along line I-II of FIG. 1A.

Referring to FIG. 7, the semiconductor package 10D may include a first substrate 100′, solder ball terminals 175, a first semiconductor chip 210, a second semiconductor chip 220, a bridge chip 300, conductive posts 510, interconnection structures 520, a first molding layer 400, a second substrate 600, an upper package 700, and a heat dissipation structure 800. However, the semiconductor package 10D might not include the first lower bumps 531, the second lower bumps 532, the first underfill layer 410, and the second underfill layer 420, which have been described above with reference to FIG. 1B.

The first substrate 100′ may be a redistribution substrate. The first substrate 100′ may include first insulating patterns 101, first redistribution patterns 130, first seed patterns 135, first seed pads 155, and first redistribution pads 150. However, the first substrate 100′ might not include the under-bump patterns 120 described above with reference to FIG. 1B. The first substrate 100′ may be in direct contact with the first semiconductor chip 210, the bridge chip 300, the interconnection structures 520, and the first molding layer 400. For example, the uppermost first insulating pattern 101 may be in direct contact with the lower surface of the first semiconductor chip 210, the lower surface of the bridge chip 300, and the lower surface of the first molding layer 400.

The first seed patterns 135 may be respectively disposed on the upper surfaces of the first redistribution patterns 130. The first seed patterns 135 that are in the uppermost first insulating pattern 101 may be electrically connected to the lower pads 215 and the interconnection structures 520. For example, the first seed patterns 135 that are in the uppermost first insulating pattern 101 may be directly connected to the lower pads 215 and the interconnection structures 520.

The first redistribution pads 150 may be disposed in the lowermost first insulating pattern 101. The first redistribution pads 150 may be respectively disposed on the lower surfaces of the lowermost first redistribution patterns 130. The first seed pads 155 may be respectively disposed on the upper surfaces of the first redistribution pads 150. The solder ball terminals 175 may be respectively disposed on the lower surfaces of the first redistribution pads 150.

The semiconductor package 10D may be manufactured by a chip-first process, but the present inventive concept is not limited thereto.

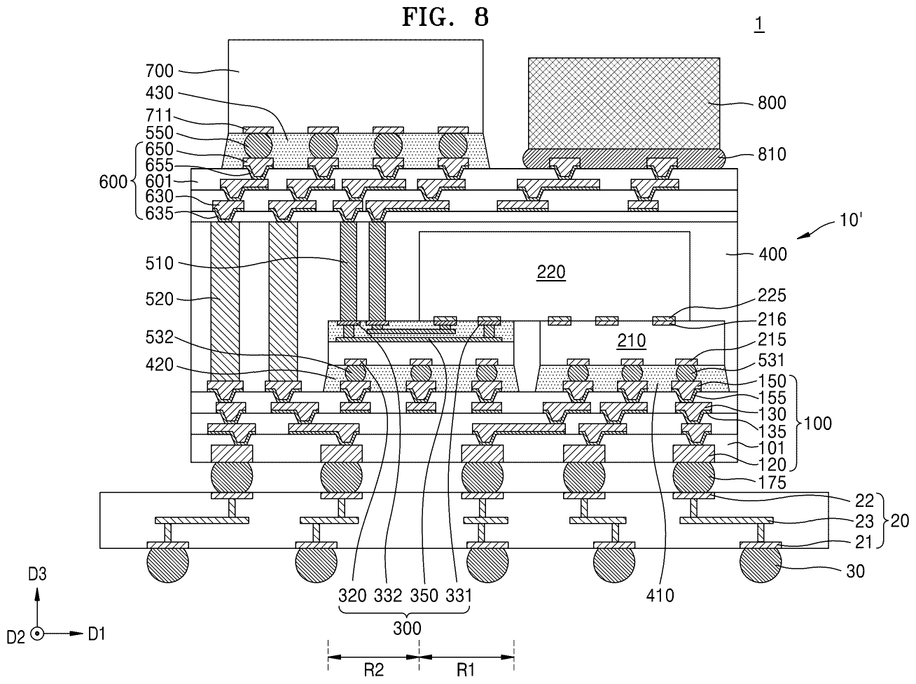

FIG. 8 is a diagram illustrating a semiconductor module 1 according to embodiments of the present inventive concept.

Referring to FIG. 8, the semiconductor module 1 may include a board 20 and a semiconductor package 10′. The board 20 may include, for example, a PCB. The board 20 may include lower metal pads 21, board wirings 23, and upper metal pads 22. The lower metal pads 21 and the upper metal pads 22 may be respectively disposed on the lower and upper surfaces of the board 20. The board wirings 23 may be disposed in the board 20. The upper metal pads 22 may be electrically connected to the lower metal pads 21 through the board wirings 23. The board wirings 23 may each include a metal material.

The semiconductor module 1 may further include board solder balls 30. The board solder balls 30 may be disposed on the lower surface of the board 20 and electrically connected to the lower metal pads 21. The board solder balls 30 may each include a solder material.

The semiconductor package 10′ may be mounted on the board 20. For example, the solder ball terminals 175 may be electrically connected to the upper metal pads 22 of the board 20 so that the semiconductor package 10′ may be electrically connected to the board 20. The semiconductor package 10′ may be substantially the same as the semiconductor package 10 described above in the examples of FIGS. 1A to IC. As an example, the semiconductor package 10′ may be substantially the same as the semiconductor package 10A of FIGS. 4A and 4B, the semiconductor package 10B of FIG. 5, the semiconductor package 10C of FIG. 6, or the semiconductor package 10D of FIG. 7.

Embodiments of the present inventive concept may be combined with each other. At least two of the embodiment of FIGS. 1A to IC, the embodiment of FIGS. 2A and 2B, the embodiment of FIG. 3, the embodiment of FIGS. 4A and 4B, the embodiment of FIG. 5, the embodiment of FIG. 6, the embodiment of FIG. 7, and the embodiment of FIG. 8 may be combined with each other.

According to embodiments of the present inventive concept, the second semiconductor chip may be disposed on the first semiconductor chip and the bridge chip and may be electrically connected to the upper package through the bridge chip and the conductive posts. Accordingly, the length of the electrical signal path between the first semiconductor chip and the upper package may be reduced. The semiconductor packages may exhibit increased performance. The semiconductor packages may be miniaturized.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package comprising:
a first substrate;
a bridge chip disposed on the first substrate and having a first region and a second region;
an upper semiconductor chip disposed on the first region of the bridge chip; and
conductive posts disposed on the second region of the bridge chip and spaced apart from the upper semiconductor chip,
wherein the upper semiconductor chip is electrically connected to the conductive posts through the bridge chip.

2. The semiconductor package of claim 1, wherein
the bridge chip comprises:
first connection pads disposed on an upper surface of the bridge chip and in the first region;
second connection pads disposed on the upper surface of the bridge chip and in the second region; and
connection structures disposed in the bridge chip and electrically connected to the first connection pads and the second connection pads,
wherein the upper semiconductor chip is electrically connected to the conductive posts through the connection structures.

3. The semiconductor package of claim 2, wherein
chip pads of the upper semiconductor chip are respectively electrically connected to the first connection pads, and
the conductive posts are respectively disposed on the second connection pads.

4. The semiconductor package of claim 1, further comprising:
a second substrate disposed on the conductive posts and the upper semiconductor chip; and
an upper package disposed on the second substrate,
wherein the upper semiconductor chip is electrically connected to the upper package through the conductive posts.

5. The semiconductor package of claim 4, wherein the upper package overlaps the conductive posts.

6. The semiconductor package of claim 4, wherein the upper package overlaps about 20% to about 40% of a planar area of the upper semiconductor chip.

7. The semiconductor package of claim 1, further comprising
a lower semiconductor chip disposed on the first substrate and spaced apart from the bridge chip,
wherein the upper semiconductor chip is disposed on a portion of the lower semiconductor chip and spaced apart from another portion of the lower semiconductor chip.

8. The semiconductor package of claim 1, further comprising
interconnection structures disposed on the first substrate and spaced apart from the bridge chip, the conductive posts, and the upper semiconductor chip,
wherein a height of the interconnection structures is greater than a height of the conductive posts,
a width of the interconnection structures is greater than a width of the conductive posts, and
a pitch of the interconnection structures is greater than a pitch of the conductive posts.

9. The semiconductor package of claim 8, wherein
the conductive posts transmit an electrical signal of the upper semiconductor chip, and
the interconnection structures receive a voltage.

10. The semiconductor package of claim 8, wherein
the height of the conductive posts is about 250 μm to about 350 μm,
the width of the conductive posts is about 80 μm to about 120 μm,
the pitch of the conductive posts is about 100 μm to about 200 μm, and
the height of the interconnection structures is about 300 μm to about 400 μm.

11. A semiconductor package comprising:
a first substrate;
a first semiconductor chip disposed on the first substrate;
a bridge chip disposed on the first substrate and spaced apart from the first semiconductor chip;
a second semiconductor chip disposed on a first region of the bridge chip and the first semiconductor chip, wherein the second semiconductor chip is electrically connected to the bridge chip and the first semiconductor chip; and
a conductive post disposed on a second region of the bridge chip and spaced apart from the second semiconductor chip,
wherein the conductive post is electrically connected to the bridge chip.

12. The semiconductor package of claim 11, further comprising:
a second substrate disposed on the conductive post and the second semiconductor chip;
an upper package disposed on the second substrate and vertically overlapping the conductive post; and
a heat dissipation structure disposed on the second substrate and spaced apart from the upper package.

13. The semiconductor package of claim 12, wherein
the heat dissipation structure overlaps the first semiconductor chip and the second semiconductor chip, and
the upper package overlaps the second semiconductor chip.

14. The semiconductor package of claim 11, wherein
the second semiconductor chip is bonded to the first semiconductor chip, and
the second semiconductor chip is bonded to the bridge chip.

15. The semiconductor package of claim 11, further comprising:
first upper bumps disposed between the first semiconductor chip and the second semiconductor chip and electrically connected to the first semiconductor chip and the second semiconductor chip; and
second upper bumps disposed between the bridge chip and the second semiconductor chip and electrically connected to the bridge chip and the second semiconductor chip.

16. The semiconductor package of claim 11, wherein
the bridge chip comprises:
a base substrate;
a bridge insulating layer disposed on the base substrate;
a first connection pad disposed on the bridge insulating layer and electrically connected to a chip pad of the second semiconductor chip;
a second connection pad disposed on the bridge insulating layer and spaced apart from the first connection pad; and
a connection structure disposed in the bridge insulating layer and electrically connected to the first connection pad and the second connection pad, and
the conductive post is disposed on the second connection pad and is electrically connected to the second connection pad.

17. The semiconductor package of claim 11, wherein a vertical gap between an upper surface of the bridge chip and an upper surface of the first substrate is about 95% to about 105% of a vertical gap between an upper surface of the first semiconductor chip and an upper surface of a first redistribution substrate.

18. A semiconductor package comprising:
a first redistribution substrate;
solder ball terminals disposed on a lower surface of the first redistribution substrate;
a first semiconductor chip mounted on the first redistribution substrate and comprising a through-via;
a bridge chip disposed on the first redistribution substrate and spaced apart from the first semiconductor chip, wherein the bridge chip has a first region and a second region;
a second semiconductor chip disposed on the first semiconductor chip and the first region of the bridge chip, wherein the second semiconductor chip is electrically connected to the first semiconductor chip and the bridge chip;
conductive posts disposed on the second region of the bridge chip and spaced apart from the first semiconductor chip;
interconnection structures disposed on the first redistribution substrate and spaced apart from the bridge chip, the conductive posts, and the second semiconductor chip;
a first molding layer disposed on the first redistribution substrate and covering the bridge chip, the first semiconductor chip, the second semiconductor chip, sidewalls of the conductive posts, and sidewalls of the interconnection structures;
a second redistribution substrate disposed on the first molding layer and electrically connected to the conductive posts and the interconnection structures;
an upper package disposed on the second redistribution substrate and vertically overlapping the conductive posts; and
a heat dissipation structure disposed on the second redistribution substrate, and spaced apart from the semiconductor package, wherein the heat dissipation structure vertically overlaps the second semiconductor chip,
wherein the second semiconductor chip is electrically connected to the upper package through the bridge chip, the conductive posts, and the second redistribution substrate,
wherein the bridge chip comprises:
a base substrate;
a bridge insulating layer disposed on the base substrate;
first connection pads disposed on an upper surface of the bridge insulating layer and electrically connected to chip pads of the second semiconductor chip;
second connection pads disposed on the upper surface of the bridge insulating layer and spaced apart from the first connection pads; and
connection structures disposed in the bridge insulating layer,
wherein the first connection pads are respectively electrically connected to the second connection pads through the connection structures, and
the conductive posts are respectively disposed on the second connection pads.

19. The semiconductor package of claim 18, wherein
the upper package overlaps at least a portion of the first semiconductor chip and at least a portion of the bridge chip,
the heat dissipation structure overlaps the first semiconductor chip, and
the heat dissipation structure comprises at least one of a heat slug, a heat sink, or a heat pipe.

20. The semiconductor package of claim 18, wherein
the first semiconductor chip comprises a logic chip,
the second semiconductor chip comprises a different type of logic chip from the first semiconductor chip, and
the upper package comprises a package substrate and a third semiconductor chip, wherein the third semiconductor chip comprises a memory chip.
